(19) United States
(12) Patent Application Publication
(10) Pub. No.: US 2012/0075004 A1
(43) Pub. Date: Mar. 29, 2012

(54) SWITCH AND METHOD OF CONTROL THE SAME

(75) Inventor: Naoyuki Miyazawa, Kanagawa (JP)

(73) Assignee: SUMITOMO ELECTRIC DEVICE INNOVATIONS, INC., Yokohama-shi (JP)

(21) Appl. No.: 13/242,174

(22) Filed: Sep. 23, 2011

(30) Foreign Application Priority Data
Sep. 28, 2010 (JP) 2010-217671

(51) Int. Cl. H03K 17/687

(52) U.S. Cl. 327/434

(57) ABSTRACT

A switch includes, a common terminal, a first terminal, a second terminal, a first FET having a first source, a first drain and a first gate, one of the first source and the first drain being coupled to the common terminal, the other of the first source and the first drain being coupled to the first terminal, and a second FET having a second source, a second drain and a second gate, one of the second source and the second drain being coupled to the common terminal, the other of the second source and the second drain being coupled to the second terminal. The first FET is controlled to a turn-off state by an absolute voltage of the first gate which is smaller than an absolute voltage of the second gate to control a turning-off state for the second transistor.

### CROSS-REFERENCE TO RELATED APPLICATION

This application is based upon and claims the benefit of priority of the prior Japanese Patent Application No. 2010-217671, filed on Sep. 28, 2010, the entire contents of which are incorporated herein by reference.

### BACKGROUND

(i) Technical Field

The present invention relates to a switch and a method of controlling the switch.

(ii) Related Art

Recently, a switch such as a high frequency switch having a plurality of terminals (Single Pole N-Through; SPNT, N is the number of the terminals) structured with a field effect transistor (FET) is used in a mobile phone treating a plurality of carrier signals. For example, Japanese Patent Application Publication No. 2006-278813 discloses a switch circuit having superior high frequency property and superior insertion loss in which a reverse breakdown voltage of a gate of a first-stage FET to which a signal having a large high-frequency amplitude is input or off capacity is reduced.

### SUMMARY

However, a circuit coupled to a high frequency switch may be broken when a mobile phone terminal having a high frequency switch receives an unnecessary signal having large electrical power, as in the case where a station is near the mobile phone terminal.

It is an object of the present invention to provide a switch protecting a circuit coupled to the switch and a method of controlling the switch.

According to an aspect of the present invention, there is provided a switch including: a common terminal; a first terminal; a second terminal; a first FET having a first source, a first drain and a first gate, one of the first source and the first drain being coupled to the common terminal, the other of the first source and the first drain being coupled to the first terminal; and a second FET having a second source, a second drain and a second gate, one of the second source and the second drain being coupled to the common terminal, the other of the second source and the second drain being coupled to the second terminal; the first FET being controlled to a turn-off state by an absolute voltage of the first gate which is smaller than an absolute voltage of the second gate to control a turning-off state for the second transistor.

According to another aspect of the present invention, there is provided a switch including: a first FET; and a second FET, one of a first source and a first drain of the first FET being coupled to a common terminal, the other of the first source and the first drain being coupled to a first terminal, voltage applied to the first gate turning on and off the first FET, one of a second source and a second drain of the second FET being coupled to the common terminal, the other of the second source and the second drain being coupled to a second terminal, voltage applied to the second gate turning on and off the second FET, ¼ or more of a signal input to the common terminal being leaked to the first FET when the first FET is turned off and the second FET is turned on.

### BRIEF DESCRIPTION OF THE DRAWINGS

FIG. 1 illustrates a circuit diagram of a high frequency switch in accordance with a comparative embodiment and a structure around the switch;

FIG. 2 illustrates a circuit diagram of a high frequency switch in accordance with a comparative embodiment and a structure around the switch;

FIG. 3A and FIG. 3B illustrate an operation of the high frequency switch in accordance with the comparative embodiment;

FIG. 4 illustrates a circuit diagram of a high frequency switch in accordance with a first embodiment and a structure around the high frequency switch;

FIG. 5A and FIG. 5B illustrate an operation of the high frequency in accordance with the first embodiment;

FIG. 6 illustrates a circuit diagram of an FET in accordance with the first embodiment;

FIG. 7 illustrates a circuit diagram of a high frequency switch in accordance with a second embodiment and a structure around the high frequency switch;

FIG. 8 illustrates an operation of the high frequency switch in accordance with the second embodiment;

FIG. 9 illustrates a circuit diagram of a high frequency switch in accordance with a third embodiment and a structure around the high frequency switch; and

FIG. 10A and FIG. 10B illustrate an operation of the high frequency switch in accordance with the third embodiment.

### DETAILED DESCRIPTION

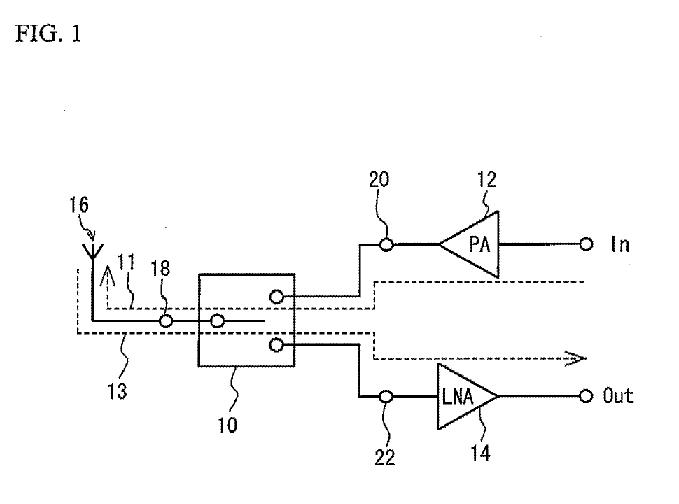

A description will be given of a comparative embodiment for comparison with an embodiment. FIG. 1 illustrates a circuit diagram of a high frequency switch 10 in accordance with the comparative embodiment and a structure around the high frequency switch 10. As illustrated in FIG. 1, the high frequency switch 10 is SP2T, and is coupled to a common terminal 18, a first terminal 20 and a second terminal 22. The common terminal 18 is coupled to the high frequency switch 10 and an antenna 16. The first terminal 20 is coupled to the high frequency switch 10 and a power amplifier (PA) 12. The second terminal 22 is coupled to the high frequency switch 10 and a low noise amplifier (LNA) 14.

The antenna 16 performs transmitting and receiving of a high frequency signal. The PA 12 amplifies a signal input from an inputting terminal In and outputs electrical power of 35 dBm at a peak to the first terminal 20. The LNA 14 amplifies a signal received by the antenna 16 and outputs the amplified signal to an outputting terminal Out. A relatively small transistor having a short gate length and a small gate width is used as the LNA 14.

The high frequency switch 10 switches between a first path (dotted line arrow 11 of FIG. 1) from the inputting terminal In to the antenna 16 via the PA 12, the first terminal 20 and the common terminal 18 and a second path (dotted line arrow 13 of FIG. 1) from the antenna 16 to the outputting terminal Out via the common terminal 18, the second terminal 22 and the LNA 14.

A description will be given of a case where a signal passes through the first path. The signal is input to the inputting terminal In. The signal is input to the PA 12 from the inputting terminal In. The signal is amplified by the PA 12 and is output to the first terminal 20. The signal is input to the antenna 16 via the first terminal 20, the high frequency switch 10 and the common terminal 18, and is transmitted from the antenna 16.

A description will be given of a case where a signal passes through the second path. The antenna 16 receives the signal. The signal is input to the common terminal 18. The signal is input to the LNA 14 via the common terminal 18, the high frequency switch 10 and the second terminal 22. The signal is amplified by the LNA 14 and is output to the outputting terminal Out.

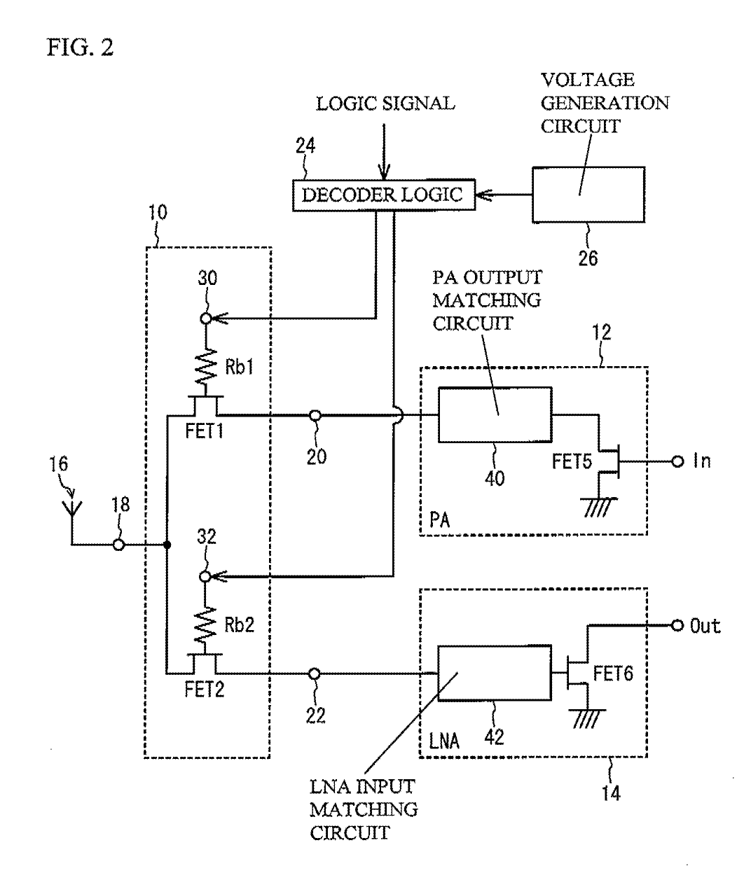

As illustrated in FIG. 2, a description will be given of details of the high frequency switch 10 in accordance with the comparative embodiment and the structure around the high frequency switch 10. In FIG. 2, the same components as those illustrated in FIG. 1 have the same reference numerals in order to avoid a duplicated explanation.

As illustrated in FIG. 2, the high frequency switch 10 has an FET 1, an FET 2, a resistor Rb1, a resistor Rb2, a control terminal 30 and a control terminal 32. A source of the FET 1 is coupled to the common terminal 18. A drain of the FET 1 is coupled to the first terminal 20. On and off of the FET 1 is controlled with a voltage applied to a gate coupled to the control terminal 30. A source of the FET 2 is coupled to the common terminal 18. A drain of the FET 2 is coupled to the second terminal 22. On and off of the FET 2 is controlled with a voltage applied to a gate coupled to the control terminal 32. The gate of the FET 1 and the gate of the FET 2 are respectively coupled to the control terminal 30 and the control terminal 32 via the resistor Rb1 and the resistor Rb2. The source and the drain of the FET 1 may be respectively coupled to the first terminal 20 and the common terminal 18. The source and the drain of the FET 2 may be respectively coupled to the second terminal 22 and the common terminal 18.

A threshold voltage of the FET 1 and the FET 2 is, for example, −2V. For example, a voltage generation circuit 26 generates two voltages of 0V and −25V and outputs the voltages to a decoder logic 24. The decoder logic 24 outputs one the signals of 0V and −25V to the control terminals 30 and 32 according to an input logic signal. For example, in a case where the logic signal is 0, the decoder logic 24 outputs the signal of 0V to the control terminal 30 and outputs the signal of −25V to the control terminal 32. In this case, the FET 1 is turned on, and the FET 2 is turned off. A signal passes through the first path 11 illustrated in FIG. 1. In a case where the logic signal is 1, the decoder logic 24 outputs the signal of −25V to the control terminal 30 and outputs the signal of 0V to the control terminal 32. In this case, the FET 1 is turned off, and the FET 2 is turned on. A signal passes through the second path 13 illustrates in FIG. 1.

The PA 12 has an FET 5 and a PA output matching circuit 40. A gate of the FET 5 is coupled to the inputting terminal In. A source of the FET 5 is coupled to the ground of the FET 5. A drain of the FET 5 is coupled to an input of the PA output matching circuit 40. The FET 5 amplifies a signal input from the inputting terminal In and outputs the amplified signal to the PA output matching circuit 40. The PA output matching circuit 40 makes impedance matching of the signal output from the PA 12 and output the signal to the first terminal 20.

The LNA 14 has an FET 6 and an LNA input matching circuit 42. A gate of the FET 6 is coupled to an output of the LNA input matching circuit 42. A source of the FET 6 is coupled to a ground. A drain of the FET 6 is coupled to the outputting terminal Out. The LNA input matching circuit 42 makes impedance matching of a signal input from the second terminal 22. The FET 6 amplifies the signal and outputs the amplified signal to the outputting terminal Out.

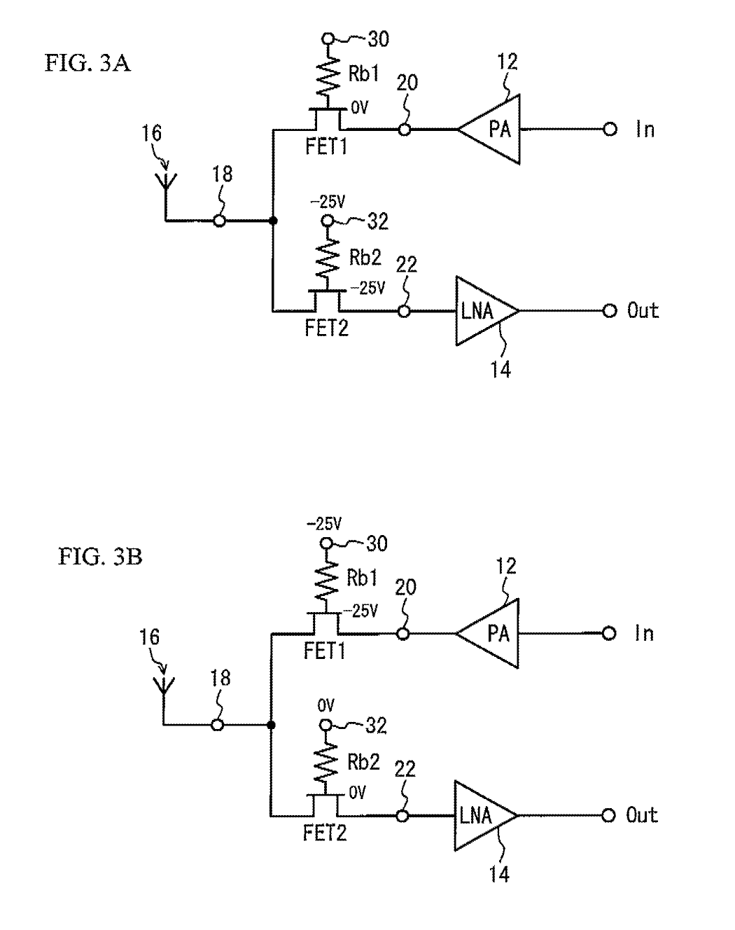

A description will be given of an operation of the high frequency switch 10 in accordance with the comparative embodiment with reference to FIG. 3A and FIG. 3B. FIG. 3A and FIG. 3B illustrate an operation of the high frequency switch 10 in accordance with the comparative embodiment. FIG. 3A and FIG. 3B are a simplified figure of FIG. 2. The same components as those illustrated in FIG. 1 and FIG. 2 have the same reference numerals in order to avoid a duplicated explanation.

FIG. 3A illustrates a condition where the FET 1 is on and the FET 2 is off. As illustrated in FIG. 3A, 0V is applied to the control terminal 30. In this case, approximately 0V is applied to the gate of the FET 1 via the resistor Rb1. Therefore, the FET 1 is turned on. −25V is applied to the control terminal 32. In this case, approximately −25V is applied to the gate of the FET 2 via the resistor Rb2. Therefore, the FET 2 is turned off.

FIG. 3B illustrates a condition where the FET 1 is off and the FET 2 is on. As illustrated in FIG. 3B, −25V is applied to the control terminal 30. In this case, approximately −25V is applied to the gate of the FET 1 via the resistor Rb2. Therefore, the FET 1 is turned off. 0V is applied to the control terminal 32. In this case, approximately 0V is applied to the gate of the FET 2 via the resistor Rb2. Therefore, the FET 2 is turned on.

In a case where electrical power of a signal received by the antenna 16 is small, there are few case where the LNA 14 is broken. However, in a case where a mobile phone terminal having the high frequency switch 10 is near a station, the antenna 16 may receive an unnecessary large signal power. In the case, it is possible that the LNA 14 coupled to the high frequency switch 10 is broken. For example, the FET 6 in the LNA 14 has short gate length and small gate width based on an assumption that a signal of a small amplitude is input. Therefore, the FET 6 is fragile.

### First Embodiment

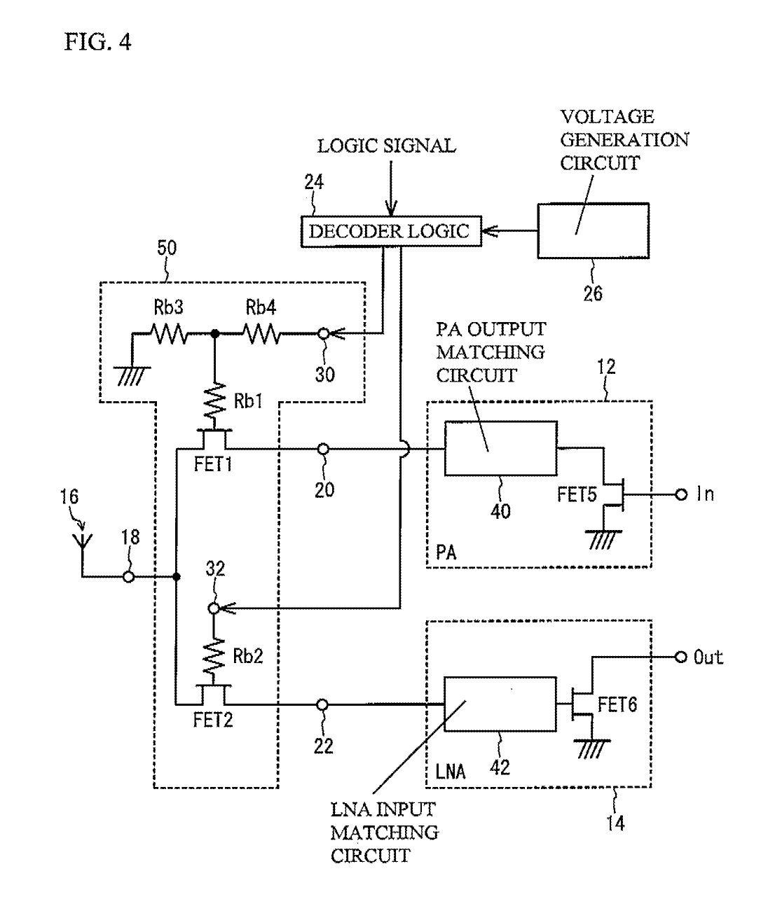

A description will be given of an embodiment solving the problem of the present invention with reference to drawings. FIG. 4 illustrates a circuit diagram of a high frequency switch 50 in accordance with a first embodiment and a structure around the high frequency switch 50. The high frequency switch 50 is different from the high frequency switch 10 in accordance with the comparative embodiment in a point that the FET 1 and the control terminal 30 are coupled to each other via a resistance division circuit structured with the resistors Rb1, Rb3 and Rb4. The other structure is the same as that of FIG. 1 through FIG. 3. Therefore, explanation of the other structure is omitted.

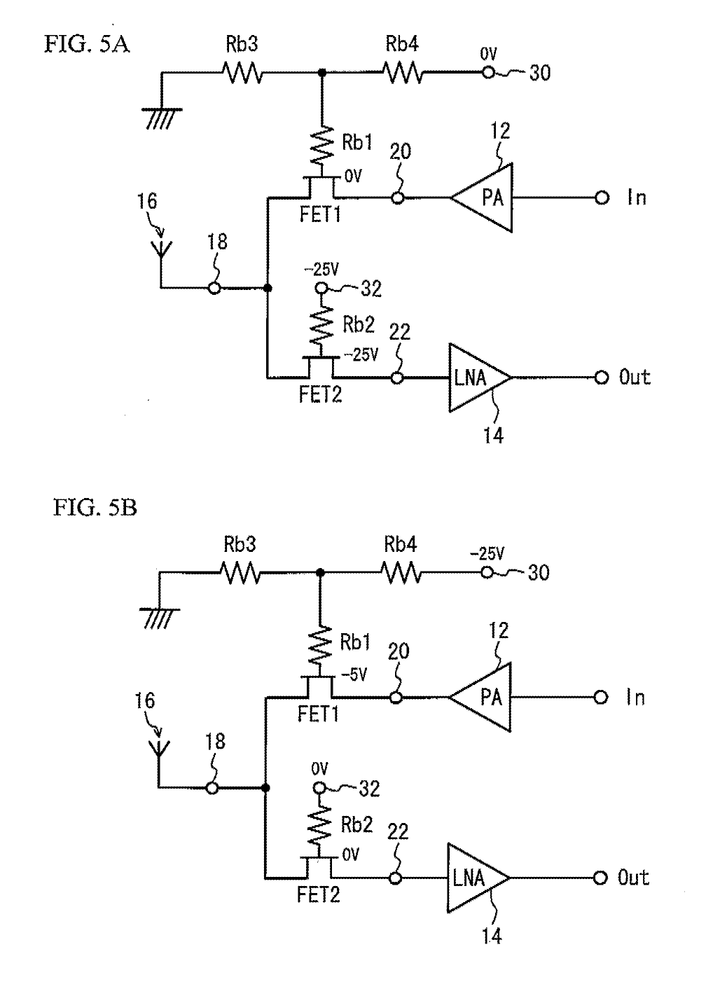

A description will be given of an operation of the high frequency switch 50 with reference to FIG. 5A and FIG. 5B. FIG. 5A and FIG. 5B illustrate an operation of the high frequency switch 50 in accordance with the embodiment and are a simplified figure of FIG. 4.

FIG. 5A illustrates a condition where the FET 1 is on and the FET 2 is off. As illustrated in FIG. 5A, 0V is applied to the control terminal 30. In this case, approximately 0V is applied to the gate of FET 1 via the resistance division circuit, because there is no potential difference between the control terminal 30 and the ground coupled to an end of the resistor Rb3. Therefore, the FET 1 is turned on. −25V is applied to the control terminal 32. In this case, approximately −25V is applied to the gate of the FET 2 via the resistor Rb2. Therefore, the FET 2 is turned off.

FIG. 5B illustrates a condition where the FET 1 is off and the FET 2 is on. As illustrated in FIG. 5B, 0V is applied to the control terminal 32. In this case, approximately 0V is applied to the gate of the FET 2 via the resistor Rb2. Therefore, the FET 2 is turned on. On the other hand, −25V is applied to the control terminal 30. In this case, −5V obtained through the division of the resistance division circuit is applied to the gate of the FET 1. Therefore, the FET 1 is off.

However, “−5V” applied to the gate of the FET 1 is closer to the threshold voltage “−2V” than “−25V” applied to the gate of the FET 1 in FIG. 3B. Therefore, the potential difference between the gate and the source of the FET 1 gets smaller when the amplitude of a signal input to the common terminal 18 is larger than a predetermined value, for example when an unnecessary large signal is input to the common terminal 18. And, in this case, the FET 1 is turned on because the drain and the source of the FET 1 fail to keep the off condition. That is, when the amplitude of the signal input to the common terminal 18 is larger than the predetermined value, the signal flows into the FET 2 side and a part of the signal passes through an on-resistance of the FET 1 and flows into the first terminal side. Thus, an unnecessary large signal flows into the PA 12 coupled to the first terminal 20 and is leaked to the ground coupled to the source of the FET 5 via the PA output matching circuit 40.

The drain of the FET 5 has a sufficient wiring width and a gate width so that large current needed for amplification passes through the drain, and is coupled to the ground with low impedance with use of a channel between the drain and the source. Thus, the FET 5 can leak an unnecessary large signal to the ground without thermal loss, even if the unnecessary large signal is input to the FET 5. Therefore, the PA 12 is not fragile. The unnecessary large signal is not leaked to the resistance division circuit from the gate of the FET 1, because the resistance between the gate of the FET 1 and the resistance division circuit is large.

For example, when the size of the FET 1 is the same as that of the FET 2 and the amplitude of a signal input to the common terminal 18 is lager than a predetermined value, approximately 3 dB corresponding to a half of the signal is leaked to the FET 1 side. It is restrained that the signal having a large amplitude flows into the LNA 14 coupled to the second terminal 22. It is therefore possible to protect the LNA 14 coupled to the high frequency switch 50. It is effective for the circuit protection that ¼ or more of the signal input to the common terminal 18 is leaked to the FET 1 side, as well as the case where approximately half of the signal input to the common terminal 18 is leaked to the FET 1 side.

In accordance with the first embodiment, an absolute value “5V” of the voltage “−5V” applied to the gate of the FET 1 acting as the first gate for turning off the FET 1 acting as the first FET is smaller than an absolute value “25V” of the voltage “−25V” applied to the gate of the FET 2 acting as the second gate for turning off the FET 2 acting as the second FET. Thus, a signal is leaked to the ground coupled to the source of the FET 5 in the PA 12 from the common terminal 18 via the FET 1 and the first terminal 20 not via the second terminal 22, when the amplitude of a signal input to the common terminal 18 is larger than a predetermined value. It is therefore possible to protect the LNA 14 coupled to the high frequency switch 50. The “predetermined value” is the amplitude of a signal so that a current flows between the drain and the source of the FET 1 when a signal is supplied from the common terminal 18 to the source (or the drain) of the FET 1 of which condition is off. The amplitude of the signal is an example of the amplitude of a signal, and may be the amplitude of voltage of a signal.

In accordance with the first embodiment, the high frequency switch 50 has a leaking portion that has a voltage depressing portion such as the resistance division circuit structured with the FET 1 acting as the first FET, the FET 2 acting as the second FET, and resistors Rb1, Rb3 and Rb4 illustrated in FIG. 2. The voltage depressing portion leaks a signal from the common terminal 18 to the ground coupled to the source of the FET 5 in the PA 12 via the FET 1 and the first terminal 20 not via the second terminal 22, and does not leak the signal when the signal is smaller than a predetermined value. It is therefore possible to protect the LNA 14 coupled to the high frequency switch 50.

In accordance with the first embodiment, the voltage depressing portion such as the resistance division circuit structured with the resistors Rb1, Rb3 and Rb4 illustrated in FIG. 4 turns off the FET 1, turns on the FET 2, and applies voltage “−5V” higher than the voltage “−25V” applied to the gate of the FET 2 in the case where the FET 1 is turned on and the FET 2 is turned off when the amplitude of the signal input to the common terminal 18 is large. That is, the voltage applied to the gate of the FET 1 in the case where the FET 1 is turned on and the FET 2 is turned off is close to the threshold voltage “−2V” of the FET 1. Thus, a part of the signal input to the common terminal 18 is leaked to the FET 1 side, because a current flows between the drain and the source of the FET 1 when the amplitude of the signal input to the common terminal 18 is large. It is therefore possible to protect the LNA 14 coupled to the FET 2 side of the high frequency switch 50.

In accordance with the first embodiment, the voltage depressing portion such as the resistance division circuit structured with the resistors Rb1, Rb3 and Rb4 illustrated in FIG. 4 depresses a given voltage “−25V” generated by the voltage generation circuit 26. When the FET 1 is turned off, the voltage “−5V” obtained through the depression of the voltage “−25V” by the voltage depressing portion is applied to the gate of the FET 1. When the FET 2 is turned off, the voltage “−25V” is applied to the gate of the FET 2 not via the voltage depressing portion. As illustrated in FIG. 5A and FIG. 5B, the voltage applied to the gate of the FET 1 and the FET 2 are three types of 0V, −5V and −25V. The voltage depressing portion such as the resistance division circuit structured with the resistors Rb1, Rb3 and Rb4 can depress the voltage “−25V” to “−5V”. Thus, the number of the voltage types generated by the voltage generation circuit 26 may be reduced from three to two of 0V and −25V. It is therefore possible to reduce the cost of the voltage generation circuit 26. The resistance division circuit is an example of the voltage depressing portion. Therefore, the voltage generated by the voltage generation circuit may be reduced with use of another circuit. The resistance division circuit may not be structured with the resistors Rb1, Rb3 and Rb4 illustrated in FIG. 4. The voltage depressing portion may depress the voltage applied to the control terminals 30 and 32 from outside.

In accordance with the first embodiment, the high frequency switch 50 has the decoder logic 24. The decoder logic 24 selects applying the voltage “−5V” obtained through the voltage depression by the voltage depressing portion such as the resistance division circuit structured with the resistor Rb1, Rb3 and Rb4 illustrated in FIG. 4 from the voltage generated by the voltage generation circuit 26 to the gate of the FET 1 or applying the voltage “−25V” generated by the voltage generation circuit 26 to the gate of the FET 2 not via the voltage depressing portion. It is therefore possible to select voltage applied to the control terminals 30 and 32 with a simple structure. The decoder logic 24 is an example of the control circuit. Another circuit may be used instead of the decoder logic 24.

In accordance with the first embodiment, the drain (or the source) of the FET 1 is coupled to the PA 12 via the first terminal 20. The drain (or the source) of the FET 2 is coupled to the LNA 14 via the second terminal 22. Thus, when the amplitude of a signal input to the common terminal 18 is larger than a predetermined value, a part of the signal is leaked to the FET 1 side. Thus, the LNA 14 is protected. The PA 12 and the LNA 14 are an example of a transmitting amplifier and a receiving amplifier. Another circuit may be used instead of the PA 12 and the LNA 14. The gate length and the gate width of the receiving amplifier are smaller than those of the transmitting amplifier based on an assumption that a signal having a small amplitude is input. Therefore, the receiving amplifier is fragile. However, the receiving amplifier is protected with the structure of the first embodiment.

In the first embodiment, it is preferable that the FET 1 and the FET 2 are a FET using nitride semiconductor. When the FET 1 and the FET 2 use the nitride semiconductor, voltage to be applied to the gate may be high voltage that is 100V or more. The voltage applied to the gate may be 0V at high level and may be −20 to −30V at low level in the FET using the nitride semiconductor. Therefore, the FET using the nitride semiconductor can handle large power. It is possible to protect the LNA 14 coupled to the high frequency switch 50 with the structure of the first embodiment, even if the amplitude of the signal input to the common terminal 18 is larger than a predetermined value in the high frequency switch 50 having the FET 1 and FET 2. The structure of the first embodiment does not need the structure in which a plurality of FETs are coupled in series and voltage is divided into the FETs. Therefore, the cost may be reduced. The FET 1 and the FET 2 may be an FET using GaAs. The threshold voltage of the FET using GaAs is −2V. And the breakdown voltage of the FET using GaAs is 10V to 20V. “0V” may be applied to the gate at high level, and “−5V” to “−8V” may be applied to the gate at low level. The FET 1 and the FET 2 may be a HEMT (High Electron Mobility Transistor) or the like.

In accordance with the first embodiment, the voltage applied to the gate of the FET 1 and the FET 2 are three types of 0V, −5V and −25V. The threshold voltage of the FET 1 and the FET 2 is −2V. These are an example. Another voltage may be used. The voltage at which the FET 1 and the FET 2 are turned on has only to be higher than the threshold voltage. For example, the absolute value of the voltage at which the FET 1 and the FET 2 are turned on has only to be higher than the absolute value of the threshold voltage. The voltage at which the off condition of the FET 2 is kept has only to be sufficiently lower than the threshold voltage, even if a signal having an amplitude at which the FET 2 is turned off that is larger than a predetermined value is input from the common terminal 18. For example, the absolute value of the voltage at which the off condition of the FET 2 is kept has only to be sufficiently lower than the absolute value of the threshold voltage. When a signal having voltage at which the FET 1 turned off and having an amplitude larger than a predetermined value is input from the common terminal 18, the voltage at which a current flows between the source and the drain of the FET 1 has only to be lower than the threshold voltage, has only to be higher than the voltage at which the FET 2 is turned off, and has only to be near the threshold voltage. For example, the absolute value of the voltage at which a current flows between the source and the drain of the FET 1 has only to be smaller than the absolute value of the threshold voltage and larger than the absolute value of the voltage at which the FET 2 is turned off.

In accordance with the first embodiment, the high frequency switch 50 is a SP2T having two terminals (the first terminal 20 and the second terminal 22). For example, a high frequency switch having three or more terminals may have the same structure as the first embodiment. In this case, a voltage depressing portion such as a resistance division circuit may be provided according to a gate of each FET coupled to each of three or more terminals, and voltage may be applied via the voltage depressing portion.

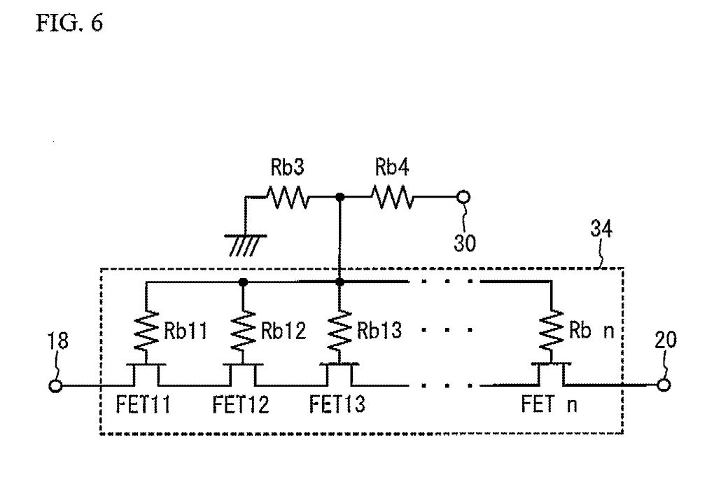

In the first embodiment, the FET 1 may have a structure in which a plurality of FETs are coupled in series as illustrated in FIG. 6. FIG. 6 illustrates a circuit diagram of an example of the FET in accordance with the first embodiment. In FIG. 6, an area surrounded by a dotted line 34 is a structure in which the FET 1 and the resistor Rb1 illustrated in FIG. 4 are replaced. The structures other than the area surrounded by the dotted line 34 are the same as FIG. 4. Therefore, explanation of the other structure is omitted. As illustrated in FIG. 6, the source and the drain of an FET 11, an FET 12, an FET 13, to an FET n are coupled to in series. The source of the FET 11 is coupled to the common terminal 18. The drain of the FET n is coupled to the first terminal 20. The gate of the FET 11, the FET 12, the FET 13, to the FET n are coupled to the control terminal 30 via the resistors Rb11, Rb12, Rb13 to Rbn and Rb4 respectively. The resistors Rb11, Rb12, Rb13 to Rbn, Rb3 and Rb4 structure the resistance division circuit. The FET 2 may have the same structure as FIG. 6.

In accordance with the first embodiment, the high frequency switch 50 is a switch treating a high frequency signal. The high frequency switch 50 is an example of a switch. The first embodiment may be adapted to a switch treating a signal other than a high frequency signal. In the first embodiment, the structures of the PA 12 and the LNA 14 are an example. The PA 12 and the LNA 14 may have another structure. In the first embodiment, the voltage generated by the voltage generation circuit 26 is an example of voltage applied to the control terminals 30 and 32. Voltage applied to the control terminals 30 and 32 from outside may be applied to the control terminals 30 and 32.

In accordance with the first embodiment, the absolute value “5V” of the voltage “−5V” applied to the gate of the FET 1 is smaller than the absolute value “25V” of the voltage “−25V” applied to the gate of the FET 2 for turning off the FET 2, when the FET 1 is turned off and the FET 2 is turned on in the control method of the high frequency switch 50. Thus, when the amplitude of the signal input to the common terminal 18 is larger than a predetermined value, the signal is leaked to the ground coupled to the source of the FET 5 in the PA 12 from the common terminal 18 via the FET 1 and the first terminal 20 not via the second terminal 22. It is therefore possible to protect the LNA 14 coupled to the high frequency switch 50.

In accordance with the first embodiment, when the FET 1 is turned off and the FET 2 is turned on, it is effective for the protection of circuit that ¼ or more of the signal input to the common terminal 18 is leaked to the FET 1. Thus, the LNA 14 coupled to the high frequency switch 50 is protected.

### Second Embodiment

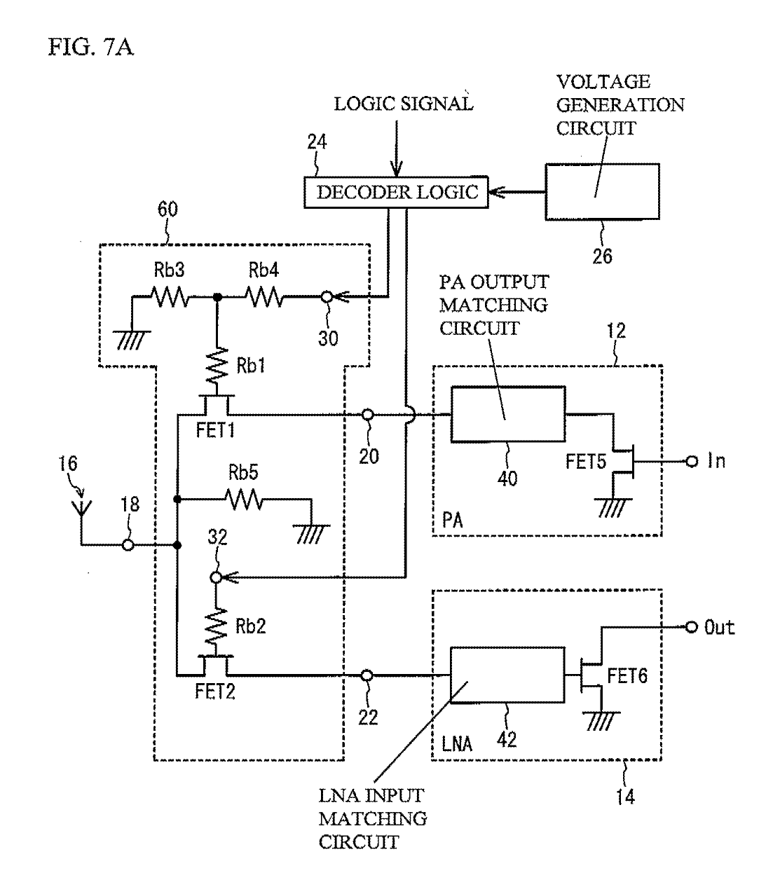

A second embodiment is a modified example of the high frequency switch 50 of the first embodiment. FIG. 7 illustrates a circuit diagram of a high frequency switch 60 in accordance with the second embodiment and a structure around the high frequency switch 60. The high frequency switch 60 is different from the high frequency switch 10 in accordance with the first embodiment in points that a resistor Rb5 is provided, one end of the resistor Rb 5 is coupled to the common terminal 18, the source of the FET 1 and the source of the FET 2, and the other end of the resistor Rb5 is coupled to the ground. In FIG. 7, the other structure is the same as FIG. 4. Therefore, explanation of the other structure is omitted.

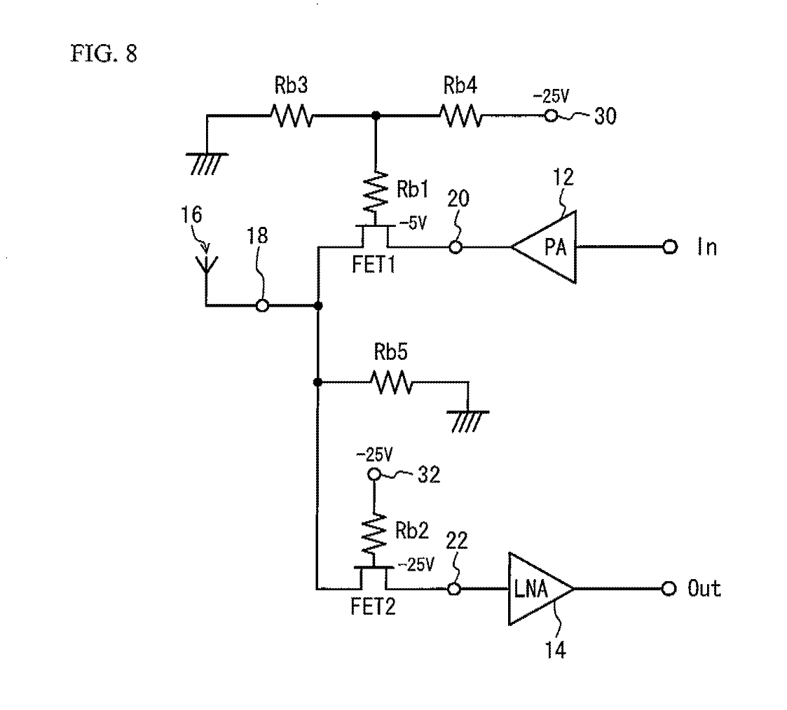

As illustrated in FIG. 8, a description will be given of an operation of the high frequency switch 60. FIG. 8 illustrates an operation of the high frequency switch 60, and is a simplified figure of FIG. 7. FIG. 8 illustrates a condition where both the FET 1 and the FET 2 are off.

As illustrated in FIG. 8, −25V is input to the control terminal 32. In this case, approximately −25V is applied to the gate of the FET 2 via the resistor Rb2. Thus, the FET 2 is turned off. Similarly, −25V is applied to the control terminal 30. In this case, −5V obtained through division of the voltage of the control terminal 30 by the resistance division circuit structured with the resistors Rb1, Rb3 and Rb4 is applied to the gate of the FET 1. Thus, the FET 1 is normally off as well as the case of FIG. 5B. When the amplitude of a signal input to the common terminal 18 is larger than a predetermined value, potential difference between the gate and the source of the FET 1 gets smaller and a current flows between the drain and the source of the FET 1. Thus, an unnecessary large signal flows into the PA 12 coupled to the first terminal 20 and is leaked to the ground coupled to the source of the FET 5 via the PA output matching circuit 40.

In this way, when the amplitude of the signal input to the common terminal 18 is larger than a predetermined value, the signal is leaked to the ground coupled to the source of the FET 5 in the PA 12 from the common terminal 18 via the FET 1. When the amplitude of the signal input to the common terminal 18 is smaller than a predetermined value, the signal is not leaked to the FET 1 side. For example, when the size (the gate width) of the FET 1 is the same as that of the FET 2, approximately 90% of the signal or more is leaked to the FET 1 side. Thus, it is restrained that the signal having a large amplitude flows into the LNA 14 coupled to the second terminal 22, as well as the first embodiment. It is therefore possible to protect the LNA 14 coupled to the high frequency switch 60.

In accordance with the second embodiment, the absolute value “5V” of the voltage “−5V” applied to the gate of the FET 1 acting as the first gate for turning off the FET 1 acting as the first FET is smaller than the absolute value “25V” of the voltage “−25V” applied to the gate of the FET 2 acting as the second gate for turning off the FET 2 acting as the second FET. Thus, an unnecessary large signal flows into the PA 12 coupled to the first terminal 20 and is leaked to the ground coupled to the source of the FET 5 via the PA output matching circuit 40. It is therefore possible to protect the LNA 14 coupled to the high frequency switch 60.

In accordance with the second embodiment, one end of the resistor Rb5 is coupled to the common terminal 18, the source of the FET 1 and the source of the FET 2. The other end of the resistor Rb5 is coupled to the ground. Thus, the voltage applied to the source of the FET 1 and the FET 2 is determined when both the FET 1 and FET 2 are turned off.

In accordance with the second embodiment, when the voltage depressing portion such as the resistance division circuit structured with the resistors Rb1, Rb3 and Rb4 illustrated in FIG. 5 applies voltage “−5V” higher than the voltage “−25V” applied to the gate of the FET 2 to the gate of the FET 1, in the case where both the FET 1 and the FET 2 are turned off. That is, the voltage applied to the gate of the FET 1 in the case where both the FET 1 and the FET 2 are turned off is close to the threshold voltage “−2V” of the FET 1. It is therefore possible to protect the LNA 14 coupled to the high frequency switch 60, as well as the first embodiment.

In accordance with the second embodiment, when both the FET 1 and the FET 2 are turned off, the absolute value “5V” of the voltage “−5V” applied to the gate of the FET 1 is smaller than the absolute value “25V” of the voltage “−25V” applied to the gate of the FET 2 for turning off the FET 2, in the control method of the high frequency switch 60. It is therefore possible to protect the LNA 14 coupled to the high frequency switch 60 as well as the first embodiment.

### Third Embodiment

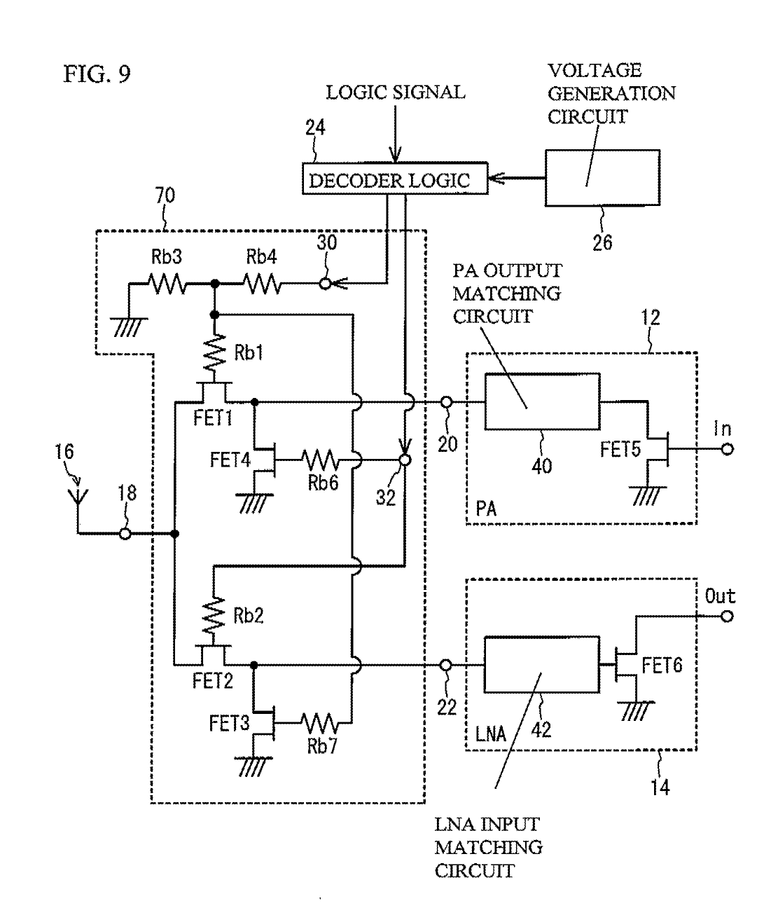

A third embodiment is another modified embodiment of the high frequency switch 50 in accordance with the first embodiment. FIG. 9 illustrates a circuit diagram of a high frequency switch 70 in accordance with the third embodiment and a structure around the high frequency switch 70. The high frequency switch 70 is different from the high frequency switch 50 in a point that an FET 3, an FET 4 and the resistors Rb6 and Rb7 are provided. The FET 3 is a shunt FET in which a drain is coupled to the second terminal 22 and the drain (or the source) of the FET 2, a source is coupled to the ground, and a gate is coupled to the control terminal 30 via a resistance division circuit structured with the resistors Rb3, Rb4 and Rb7. The resistance division circuit structured with the resistors Rb3, Rb4 and Rb7 divides the voltage applied to the control terminal 30. The divided voltage is applied to the gate of the FET 3. The FET 4 is a shunt FET in which a drain is coupled to the first terminal 20 and the drain (or the source) of the FET 1, a source is coupled to the ground, and a gate is coupled to the control terminal 32 via the resistor Rb6. In FIG. 9, the other structure is the same as FIG. 4. Therefore, explanation of the other structure is omitted.

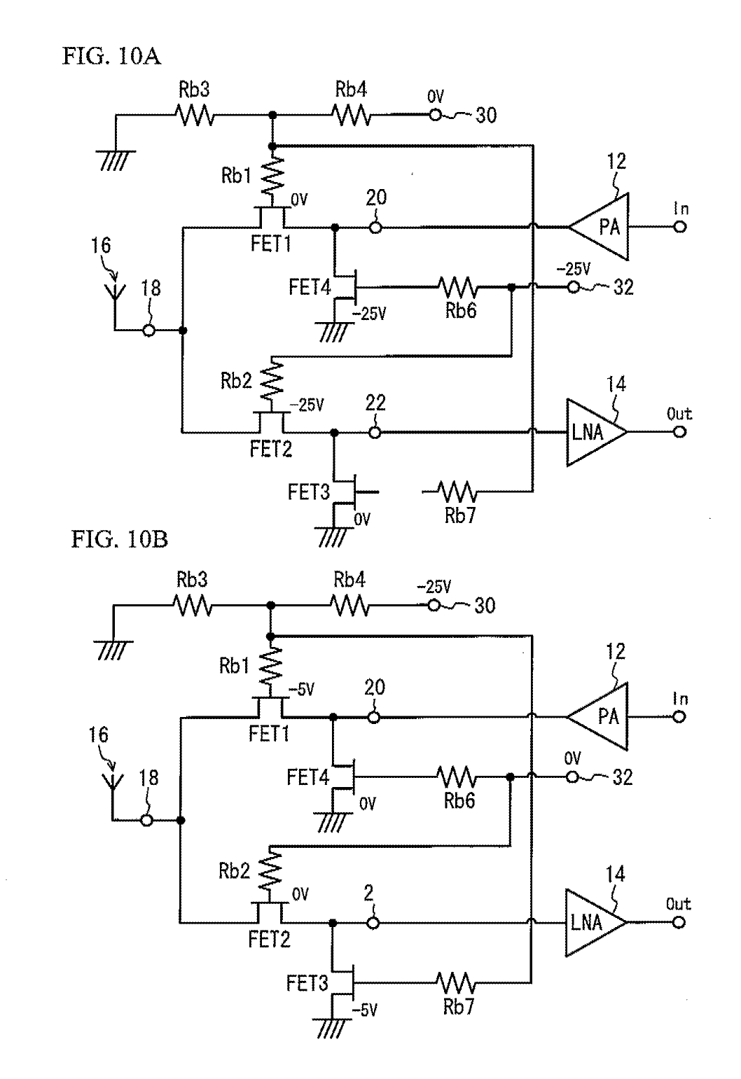

A description will be given of an operation of the high frequency switch 70 with reference to FIG. 10A and FIG. 10B. FIG. 10A and FIG. 10B illustrate an operation of the high frequency switch 70, and are a simplified figure of FIG. 9.

FIG. 10A illustrates a condition where the FET 1 and the FET 3 are on, and the FET 2 and the FET 4 are off. As illustrated in FIG. 10A, 0V is applied to the control terminal 30. In this case, approximately 0V is applied to the gate of FET 1 via the resistance division circuit structured with the resistors Rb1, Rb3 and Rb4, because there is no potential difference between the control terminal 30 and the ground coupled to an end of the resistor Rb3. Therefore, the FET 1 is turned on. Similarly, the FET 3 is turned on. “−25V” is applied to the control terminal 32. In this case, approximately −25V is applied to the gate of the FET 2 via the resistor Rb2. Therefore, the FET 2 is turned off. Similarly, the FET 4 is turned off.

FIG. 10B illustrates a condition where the FET 1 and the FET 3 are off and the FET 2 and the FET 4 are on. As illustrated in FIG. 10B, 0V is applied to the control terminal 32. In this case, approximately 0V is applied to the gate of the FET 2 via the resistor Rb2. Therefore, the FET 2 is turned on. Similarly, the FET 4 is turned on. On the other hand, −25V is applied to the control terminal 30. In this case, −5V obtained through the division of the resistance division circuit structured with the resistors Rb1, Rb3 and Rb4 is applied to the gate of the FET 1. Therefore, the FET 1 is normally off as well as the case of FIG. 5B. However, the potential difference between the gate and the source of the FET 1 gets smaller and a current flows between the drain and the source of the FET 1 when the amplitude of a signal input to the common terminal 18 is larger than a predetermined value. Similarly, a current flows between the drain and the source of the FET 3. When the amplitude of the signal input to the common terminal 18 is larger than the predetermined value, the signal flows into the FET 2 side and a part of the signal is leaked to the FET 1 side. In this case, the signal is leaked to the ground coupled to the source of the FET 4 via the FET 1. Further, a part of the signal flowing into the FET 2 side is leaked to the ground coupled to the source of the FET 3 via the FET 3 not via the second terminal 22. Thus, it is restrained that the signal having a large amplitude flows into the LNA 14 coupled to the second terminal 22. It is therefore possible to protect the LNA 14 coupled to the high frequency switch 70.

In accordance with the third embodiment, the high frequency switch 70 has the FET 3 acting as the third FET in which a source is coupled to the source of the FET 2, and a drain is coupled to the ground. When the FET 2 is turned on and the FET 3 is turned off, the absolute value “5V” of the voltage “−5V” applied to the gate of the FET 3 acting as the third gate for turning off the FET 3 is smaller than the absolute value “25V” of the voltage “−25V” applied to the gate of the FET 2 acting as the second gate for turning off the FET 2. Thus, a part of the signal flowing into the FET 2 side is leaked to the ground coupled to the source of the FET 3 via the FET 3 not via the second terminal 22. It is therefore possible to protect the LNA 14 coupled to the high frequency switch 70.

In accordance with the third embodiment, when the FET 1 and FET 3 are off and the FET 2 is on and the amplitude of the signal input to the common terminal 18 is larger than a predetermined value, the resistance division circuit structured with the resistors Rb3, Rb4 and Rb7 applies the voltage “−5V” higher than the voltage “−25V” applied to the gate of the FET 2 in the case where the FET 1 and the FET 3 are turned on and the FET 2 is turned off to the gate of the FET 3. Thus, the signal is leaked to the ground coupled to the source of the FET 3 from the common terminal 18. It is therefore possible to protect the LNA 14 coupled to the high frequency switch 70.

In accordance with the third embodiment, as illustrated in FIG. 10B, when the amplitude of the signal input to the common terminal 18 is larger than a predetermined value, “−5V” obtained through division of “−25V” applied to the common terminal 30 is applied to the gate of the FET 1 and the FET 3. Thus, a part of the signal input to the common terminal 18 is leaked to the FET 1 side. A part of the signal flowing into the FET 2 side is leaked to the ground coupled to the source of the FET 3 via the FET 3 not via the second terminal 22. In FIG. 10B, when “−25V” is applied to the control terminal 30, “−5V” obtained through division of “−25V” by the resistance division circuit may be applied to the gate of the FET 3. Approximately “−25V” may be applied to the gate of the FET 1 not via the resistance division circuit.

The present invention is not limited to the specifically disclosed embodiments and variations but may include other embodiments and variations without departing from the scope of the present invention.

What is claimed is:

1. A switch comprising:
a common terminal;
a first terminal;
a second terminal;
a first FET having a first source, a first drain and a first gate, one of the first source and the first drain being coupled to the common terminal, the other of the first source and the first drain being coupled to the first terminal; and
a second FET having a second source, a second drain and a second gate, one of the second source and the second drain being coupled to the common terminal, the other of the second source and the second drain being coupled to the second terminal;
the first FET being controlled to a turn-off state by an absolute voltage of the first gate which is smaller than an absolute voltage of the second gate to control a turning-off state for the second transistor.

2. The switch according to claim 1, further comprising a voltage depressing portion for generating the absolute voltage for controlling the turning-off state of the first FET.

3. The switch according to claim 2, wherein the voltage depressing position is a resistive divider.

4. The switch according to claim 1, further comprising a third FET having a third source, a third drain and a third gate, one of the third source and the third drain being coupled to the other of the second source and the second drain of the second transistor, the other of the third source and the third drain being coupled to ground, the third FET being controlled to a turning-off state by an absolute voltage of the third gate which is smaller than an absolute voltage of the second gate to control the tuning-off state for the second transistor.

5. The switch as claimed in claim 1,
wherein:
the other of the first source and the first drain is coupled to a transmitting amplifier; and
the other of the second source and the second drain is coupled to a receiving amplifier.

6. The switch as claimed in claim 1, wherein the first FET and the second FET are an FET using nitride semiconductor.

7. The switch as claimed in claim 1 further comprising a decoder controlling voltage applied to the first gate of the first FET and the second gate of the second FET.

8. The switch as claimed in claim 1, wherein the first FET is comprised of a plurality of FETs coupled in series.

9. The switch as claimed in claim 1, wherein gate width of the first gate of the first FET is the same as the gate width of the second gate of the second FET.

10. The switch as claimed in claim 1 further comprising a resistor,
wherein:
one end of the resistor is coupled to the first source of the first FET and the second source of the second FET; and
the other end of the resistor is coupled to ground.

11. A method of controlling a switch having a common terminal, a first terminal, a second terminal, a first FET having a first source, a first drain and a first gate, one of the first source and the first drain being coupled to the common terminal, the other of the first source and the first drain being coupled to the first terminal, and a second FET having a second source, a second drain and a second gate, one of the second source and the second drain being coupled to the common terminal, the other of the second source and the second drain being coupled to the second terminal, comprising:
controlling the first FET to a turning-off state a voltage of the first gate of the first FET, an absolute voltage of the voltage of the first gate being smaller than an absolute voltage of a voltage of the second gate to control a turning-off state of the second FET.

12. The method as claimed in claim 11, wherein the first terminal connected to a transmitting amplifier and the second terminal connected to a receiving amplifier.

13. A switch comprising:
a first FET; and
a second FET,
one of a first source and a first drain of the first FET being coupled to a common terminal,
the other of the first source and the first drain being coupled to a first terminal,
voltage applied to the first gate turning on and off the first FET,
one of a second source and a second drain of the second FET being coupled to the common terminal,
the other of the second source and the second drain being coupled to a second terminal,
voltage applied to the second gate turning on and off the second FET,
¼ or more of a signal input to the common terminal being leaked to the first FET when the first FET is turned off and the second FET is turned on.

14. The switch as claimed in claim 13, further comprising a decoder controlling voltage applied to the first gate of the first FET and the second gate of the second FET.

15. The switch as claimed in claim 13, wherein the first FET is composed of a plurality of FETs coupled in series.

16. The switch as claimed in claim 16, wherein gate width of the first gate of the first FET is the same as the gate width of the second gate of the second FET.

17. The switch as claimed in claim 16 further comprising a resistor,
wherein:
one end of the resistor is coupled to the first source of the first FET and the second source of the second FET; and
the other end of the resistor is coupled to ground.
